(19) United States
(12) Patent Application Publication
(10) Pub. No.: US 2010/0243043 A1
(43) Pub. Date: Sep. 30, 2010

(54) Light Absorbing Layer Of CIGS Solar Cell And Method For Fabricating The Same

(76) Inventor: Chuan-Lung Chuang, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/410,462

(22) Filed: Mar. 25, 2009

(51) Int. Cl. H01L 31/00; C23C 14/34

(52) U.S. Cl. 136/256; 204/192.28

(57) ABSTRACT

A light absorbing layer of a CIGS solar cell and a method for fabricating the same are provided. According to the present invention, a cuprous sulfide layer is prepared by a sputtering process. Then, a CIGS sol-gel solution is provided onto the cuprous sulfide layer by an immersion coating, spin coating, printing, or spray coating process. The CIGS sol-gel solution is then baked to form a plurality of a CIGS stack layers containing copper (Cu), indium (In), gallium (Ga), and selenium (Se). A rapid thermal process is then conducted for melting the cuprous sulfide layer and the CIGS stack layers to form a copper/indium/gallium/sulfur/selenium (CIGSS) light absorbing layer. The CIGSS light absorbing layer is provided for a solar cell to improve the photoelectric transformation efficiency and the light absorbance.

### BACKGROUND OF THE INVENTION

1. Field of the Invention

The present invention relates generally to a copper indium gallium diselenide (CIGS) solar cell, and more particularly, to a light absorbing layer of a CIGS solar cell and a method for fabricating the same.

2. The Prior Arts

Sources of fossil fuel had been mined and non-renewably consumed for many years, and are almost exhausted from the earth. It is a critical concern for the human being to find out reliable alternative energy sources for even the basic survival. Biomass energy, geothermal energy, wind energy, and nuclear energy are all in consideration. However, when further in view of factors of reliability, security, and environment protection, none of them can be comparable to solar energy taken from the sunlight radiation. Almost everywhere of the earth can be irradiated by the sunlight, and the sunlight can be received and converted into electric energy without producing any contaminant. Therefore, solar energy is so far the cleanest alternative energy source.

A solar cell is a device for converting the sunlight energy into electric energy which can be conveniently used. There are many kinds of solar cells developed and fabricated for satisfying different demands. Among all of these kinds, more attention had been paid to CIGS solar cells having high absorbing efficiency and high photoelectric conversion efficiency.

In general, the CIGS solar cell is derived from a copper indium diselenide (CIS) solar cell. The CIS solar cell includes CuInSe₂ layer. CuInSe₂ is a semiconductor having a direct bandgap, and especially having a very high absorbance. The forbidden bandwidth (Eg) of CuInSe₂ is 1 eV which is less than the forbidden bandwidth of 1.4 to 1.5 eV which is believed as most suitable for a solar cell. As such, CuInSe₂ is mixed with CuGaSe₂ having a higher forbidden bandwidth (Eg=1.6 eV) to form the compound of Cu(InGa)Se₂ known as a CIGS polycrystalline material for increasing the forbidden bandwidth.

FIG. 1 is a schematic diagram illustrating a conventional CIGS solar cell 1. Referring to FIG. 1, the CIGS solar cell 1 typically includes a glass substrate 10, a back electrode layer 20, a CIGS light absorbing layer 30, a buffer layer 80, and a transparent electrode layer 90. The back electrode layer 20 is provided for electric conduction, and is typically made of molybdenum. The CIGS light absorbing layer 30 is a p-type semiconductor layer. The buffer layer 80 is an n-type semiconductor layer, and typically made of cadmium sulfide (CdS). The transparent electrode layer 90 is typically made of aluminum zinc oxide (AZO), indium zinc oxide (IZO), or indium tin oxide (ITO), which has a high light transparency and a high electric conductivity. As shown in FIG. 1, a sunlight L is downwardly incident to the CIGS solar cell 1. Thereafter, the sunlight L enters the transparent electrode layer 90, and then passes through the buffer layer 80, and reaches to the CIGS light absorbing layer 30. The CIGS light absorbing layer 30 absorbs the sunlight L and produces electron hole pairs which are transferred to the transparent electrode layer 90 and the back electrode layer 20, respectively, and thereby the electric energy is produced for power supplying.

FIG. 2 is a schematic diagram illustrating another conventional CIGS solar cell. Referring to FIG. 2, in order to improve the adhesivity of the CIGS light absorbing layer 30 to the back electrode layer 20, an alloy layer 22 containing molybdenum (Mo), copper (Cu), aluminum (Al), and silver (Ag) is provided as a intermediate layer disposed between the CIGS light absorbing layer 30 and the back electrode layer 20 for enhancing the adhesivity therebetween. Further, a cuprous sulfide (or cuprous selenide) layer 24 is disposed on the alloy layer 22 for compensating the difference between the thermal expansion coefficients of the alloy layer 22 and those of the light absorbing layer 30, so as to avoid the alloy layer 22 and the light absorbing layer 30 from peeling off one from another caused by a shearing effect generated at the interface therebetween in subsequent thermal treatment process due to the difference in the thermal expansion coefficients between adjacent layers.

FIG. 3 shows an absorption spectrum of a conventional CIGS light absorbing layer. Referring to FIG. 3, the conventional CIGS light absorbing layer includes CuGaSe₂ and CuInSe₂. As shown in FIG. 3, the absorption spectrum of CuGaSe2 is mainly falling within the wavelength range from 370 nm to 735 nm with a light absorbance ranging from 4% to 8%. And the absorption spectrum of CuInSe₂ is mainly falling within the wavelength range from 550 nm to 1170 nm with a light absorbance ranging from 6% to 10%. However, it can also be learnt that when comparing with the solar spectrum, there still leaves a great percentage of light in a wavelength range from 700 nm to 900 nm not well utilized.

Further, the conventional CIGS light absorbing layers as discussed above are usually formed by an evaporation deposition, a sputtering deposition, or an electrochemical deposition method, and all these methods involve a vacuum processing which requires expensive equipment investment. Alternatively, as a non-vacuum technology, the ink printing method was developed by International Solar Electric Technology Inc., (ISET). According to the ink printing method, metal or oxide nanoparticles are first prepared, and are then mixed with a suitable solvent thus forming a slurry. Then, the slurry is provided onto the molybdenum layer to form the CIGS light absorbing layer by, for example, an ink process, and thereby the fabrication cost can be greatly reduced.

However, all of the aforementioned light absorbing layers are disadvantageously restricted by the intrinsic absorbing properties of CuGaSe₂ and CuInSe₂. Therefore, there is about 50% of the light in the wavelength range from 700 nm to 900 nm cannot be sufficiently utilized. As such, the overall light absorbance efficiency cannot be further improved, and the photoelectric transformation efficiency of the CIGS solar cell having such a light absorbing layer is not good enough.

Accordingly, a light absorbing layer having an improved photoelectric transformation efficiency and a method for fabricating the same are desired. According to this method, a sol-gel solution is provided on the substrate by non-vacuum method followed by a rapid thermal process to form a light absorbing layer having a high light absorbance. In such a way, the absorbance of the light in the wavelength range from 700 nm to 900 nm can be improved, and thus providing a solution to solve the difficulty in the all of the aforementioned conventional light absorbing layers.

### SUMMARY OF THE INVENTION

A primary objective of the present invention is to provide a light absorbing layer of a CIGS solar cell. According to the present invention, a molybdenum conductive layer and an alloy layer containing molybdenum (Mo), copper (Cu), aluminum (Al), and silver (Ag) ingredients are sequentially stacked onto a glass substrate from bottom to top. Then, a cuprous sulfide layer is configured on the alloy layer, and then a plurality of CIGS stack layers containing copper (Cu), indium (In), gallium (Ga), and selenium (Se), are formed on the cuprous sulfide layer. Then, a thermal treatment is conducted thereto so as to form a copper/indium/gallium/sulfur/selenium (CIGSS) light absorbing layer. The CIGSS light absorbing layer is provided, and followed by stacking a buffer layer and a transparent electrode layer thereupon, thus a CIGS solar cell having an improved photoelectric transformation efficiency and an improved light absorbance is formed.

Further, the present invention is also directed to provide a method for fabricating a light absorbing layer of a CIGS solar cell. According to the method of the present invention, a cuprous sulfide layer is prepared by a sputtering process. Then, a sol-gel solution containing copper (Cu), indium (In), gallium (Ga), and selenium (Se) is provided onto the cuprous sulfide layer by an immersion coating, spin coating, printing, or spray coating process. This sol-gel solution is then baked to form a plurality of a CIGS stack layers containing copper (Cu), indium (In), gallium (Ga), and selenium (Se). A rapid thermal process is then conducted for melting the cuprous sulfide layer and the CIGS stack layers to form a copper/indium/gallium/sulfur/selenium (CIGSS) light absorbing layer. The CIGSS light absorbing layer is provided, and followed by stacking a buffer layer and a transparent electrode layer thereupon, thus a CIGS solar cell having an improved photoelectric transformation efficiency and an improved light absorbance is formed.

According to the present invention, a light absorbing layer having an improved photoelectric transformation efficiency can be achieved for improving the absorbance to the sunlight within the wavelength range from 700 nm to 900 nm, thus improving the overall light absorbance and photoelectric transformation efficiency of the CIGS solar cell, and providing a solution to the disadvantages of the conventional technologies.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a conventional CIGS solar cell;

FIG. 2 is a schematic diagram illustrating another conventional CIGS solar cell;

FIG. 3 shows a thin film absorption spectrum of a conventional CIGS light absorbing layer;

FIG. 4 is a schematic diagram illustrating a structure of a first embodiment of the present invention;

FIG. 5 is a flow chart illustrating a fabrication flow of the first embodiment of the present invention;

FIG. 6 illustrates the flow chart of forming the CIGS stack layers of the first embodiment of the present invention;

FIG. 7 is a flow chart illustrating the melting thermal treatment of the first embodiment of the present invention;

FIG. 8 is a heating curve of the first embodiment of the present invention;

FIG. 9 is a schematic diagram illustrating a structure of a second embodiment of the present invention;

FIG. 10 illustrates the flow chart of forming the CIGS stack layers of the second embodiment of the present invention;

FIG. 11 is a schematic diagram illustrating a structure of a third embodiment of the present invention;

FIG. 12 illustrates the flow chart of forming the CIGS stack layers of the third embodiment of the present invention; and

FIG. 13 shows a thin film absorption spectrum of the present invention.

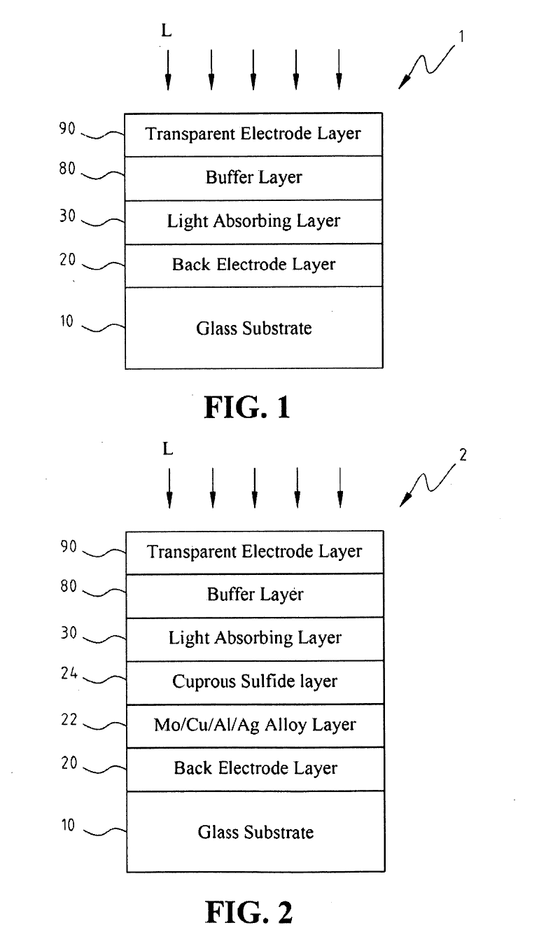

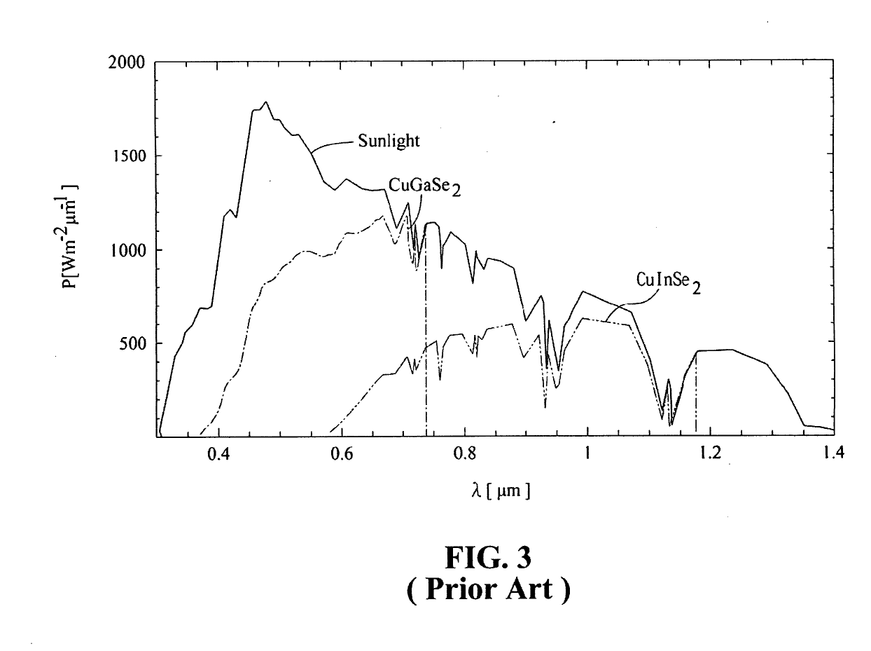

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

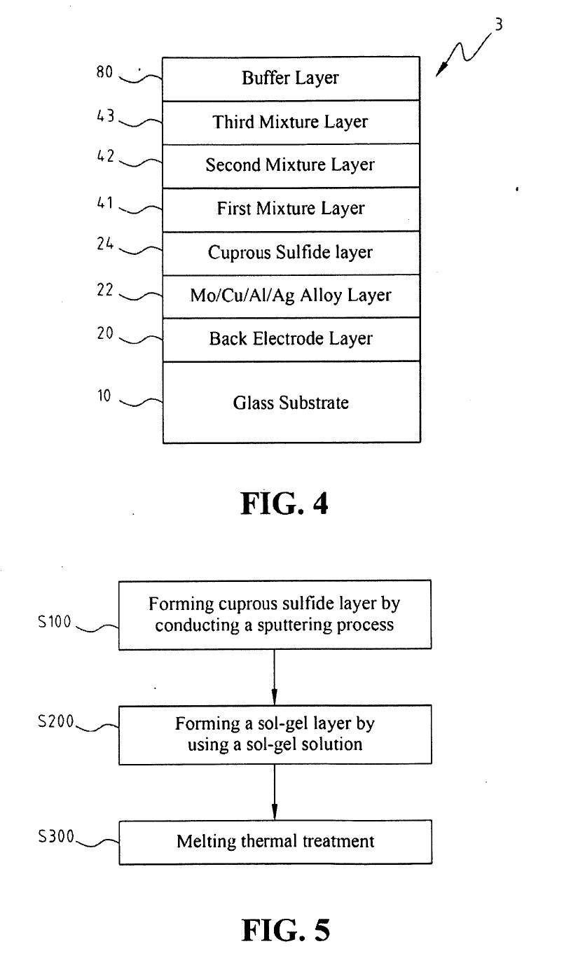

FIG. 4 is a schematic diagram illustrating a structure of a first embodiment of the present invention. Referring to FIG. 4, a copper/indium/gallium/selenium (CIGS) solar cell 3 is shown. The CIGS solar cell 3 includes a glass substrate 10, a molybdenum (Mo) thin film layer serving as a back electrode layer 20, a Mo/Cu/Al/Ag alloy layer 22, a cuprous sulfide layer 24, a first mixture layer 41, a second mixer layer 42, a third mixer layer 43, and a buffer layer 80 sequentially stacked one on another from bottom to top. Specifically, the back electrode layer 20 and the Mo/Cu/Al/Ag alloy layer 22 are sequentially deposited onto the glass substrate 10. Thereafter, the cuprous sulfide layer 24, the first mixture layer 41, the second mixer layer 42, and the third mixer layer 43 are then sequentially stacked onto the Mo/Cu/Al/Ag alloy layer 22. A thermal treatment is conducted to the cuprous sulfide layer 24, the first mixture layer 41, the second mixer layer 42, and the third mixer layer 43 to form a copper/indium/gallium/sulfur/selenium (CIGSS) light absorbing layer. Then, the buffer layer 80 and a transparent electrode layer (not shown in the drawing) are deposited onto the third mixer layer 43.

The first mixture layer 41 includes cuprous selenide and gallium selenide. The second mixture layer 42 includes indium selenide and gallium selenide. The third mixture layer 43 includes cuprous selenide and indium selenide. The first mixture layer 41, the second mixture layer 42, and the third mixture layer 43 together form a CIGS stack layer.

FIG. 5 is a flow chart illustrating a fabrication flow of the first embodiment of the present invention. Referring to FIG. 5, the flow of the fabrication starts from step S100. At step S100, a glass substrate having a back electrode layer and a Mo/Cu/Al/Ag alloy layer sequentially deposited thereupon is provided, and a cuprous sulfide is taken as a sputtering target to be bombarded for forming a cuprous sulfide layer on the Mo/Cu/Al/Ag alloy layer, and then the flow enters step S200. In step S200, a sol-gel solution containing Cu, In, Ga, and Se is provided for forming a plurality of CIGS stack layers on the cuprous sulfide layer, and then the flow enters step S300. In step S300, a melting thermal treatment is conducted so that the cuprous sulfide layer and the CIGS stack layers are molten and mutually diffused, thus forming a copper/indium/gallium/sulfur/selenium (CIGSS) light absorbing layer having a relatively high light absorbance.

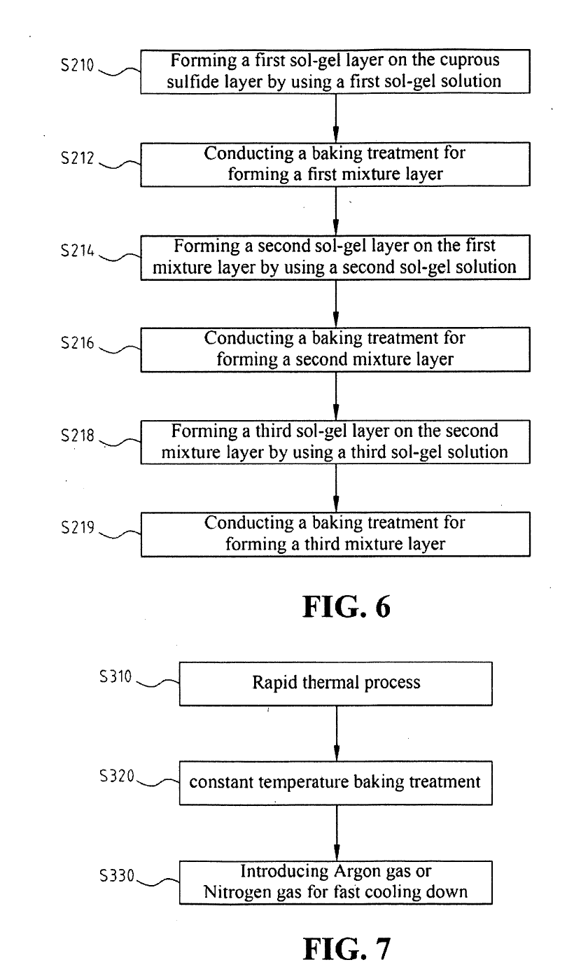

FIG. 6 illustrates the flow chart of forming the CIGS stack layers of the first embodiment of the present invention. Referring to FIG. 6, in step S210, a first sol-gel solution containing cuprous selenide and gallium selenide is provided for forming a first sol-gel layer on the cuprous sulfide layer by conducting an immersion coating, or spin coating, or printing, or spray coating process, and then the flow enters step S212. In step S212, a baking treatment is conducted thereto at a baking temperature in a range from 60° C. to 150° C. for 10 to 20 minutes, during which the solvent contained in the first sol-gel layer is removed, and therefore a first mixture layer is formed. The first mixture layer includes cuprous selenide and gallium selenide, and then the flow enters step S214.

In step S214, a second sol-gel solution containing indium selenide and gallium selenide is provided for configuring a second sol-gel layer on the first mixture layer by conducting an immersion coating, or spin coating, or printing, or spray coating process, and then the flow enters step S216. In step S216, a drying treatment is conducted thereto at a drying temperature in a range from 60° C. to 150° C. for 10 to 20 minutes, during which the solvent contained in the second sol-gel layer is removed, and therefore a second mixture layer is configured. The second mixture layer includes indium selenide and gallium selenide, and then the flow enters step S218.

In step S218, a third sol-gel solution containing cuprous selenide and indium selenide is provided for forming a third sol-gel layer on the second mixture layer by conducting an immersion coating, or spin coating, or printing, or spray coating process, and then the flow enters step S219. In step S219, a baking treatment is conducted thereto at a baking temperature in a range from 60° C. to 150° C. for 10 to 20 minutes, during which the solvent contained in the third sol-gel layer is removed, and therefore a third mixture layer is formed. The third mixture layer includes cuprous selenide and indium selenide. In such a way, the CIGS stack layer including the first mixture layer, the second mixture layer, and the third mixture layer is obtained.

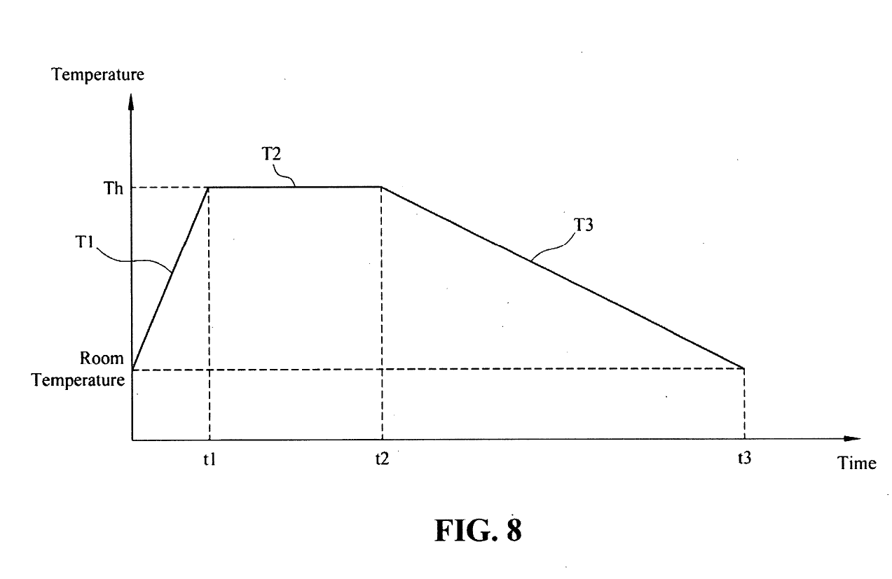

FIG. 7 is a flow chart illustrating the melting thermal treatment of the first embodiment of the present invention. FIG. 8 is a heating curve of the first embodiment of the present invention Referring to FIG. 7, in step S310, a rapid thermal process is conducted with a temperature rising rate of 5° C./sec to 10° C./sec to raise the temperature up to a melting temperature Th (about 400° C. to 800° C.) until a time point t1 as shown as the T1 temperature curve in FIG. 8. Then, the flow enters step S320, in step S320, during a time period from the time point t1 to a time point t2, a constant temperature baking treatment is conducted at the melting temperature Th for about 10 minutes to 20 minutes, as shown as the T2 temperature curve in FIG. 8. Therefore, the cuprous sulfide layer, the first mixture layer, the second mixture layer, and the third mixture layer are molten and mutually diffused, and then the flow enters step S330. In step S330, a cooling gas is introduced for fast cooling treatment so as to lower the temperature down to 50° C. to 200° C. during a time period from the time point t2 to a time point t3 (about 40 minutes to 180 minutes), as shown as the temperature curve in FIG. 8. The cooling gas for example can be argon gas or nitrogen gas. In such a way, a CIGSS light absorbing layer having a relatively high light absorbance is obtained.

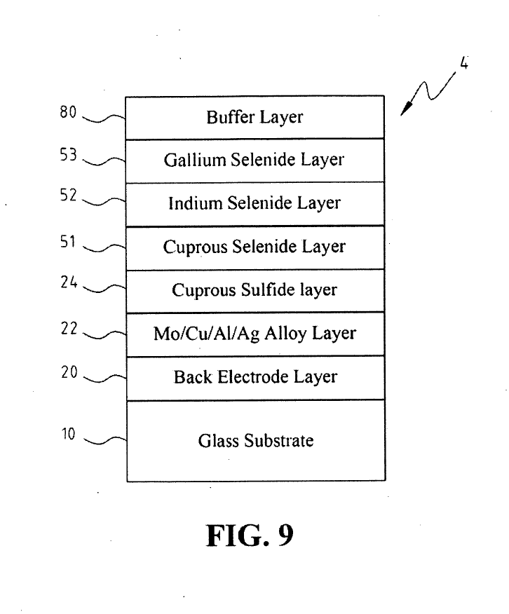

FIG. 9 is a schematic diagram illustrating a structure of a second embodiment of the present invention. Referring to FIG. 9, a CIGS solar cell 4 is shown. The CIGS solar cell 4 includes a glass substrate 10, a molybdenum (Mo) thin film layer serving as a back electrode layer 20, a Mo/Cu/Al/Ag alloy layer 22, a cuprous sulfide layer 24, a cuprous selenide layer 51, an indium selenide layer 52, a gallium selenide layer 52, and a buffer layer 80 sequentially stacked one on another from bottom to top. Specifically, the cuprous sulfide layer 24, the cuprous selenide layer 51, the indium selenide layer 52, and the gallium selenide layer 53 are sequentially stacked onto the Mo/Cu/Al/Ag alloy layer 22, and followed by a thermal treatment so that the cuprous sulfide layer 24, the cuprous selenide layer 51, the indium selenide layer 52, and the gallium selenide layer 53 are molten and mutually diffused to form a copper/indium/gallium/sulfur/selenium (CIGSS) light absorbing layer having a high light absorbance. Then, the buffer layer 80 and a transparent electrode layer (not shown in the drawing) are sequentially deposited onto the gallium selenide layer 53.

The cuprous sulfide layer 24 of FIG. 9 is similar to that of FIG. 4, and therefore the method of forming the cuprous sulfide layer 24 is not to be iterated hereby.

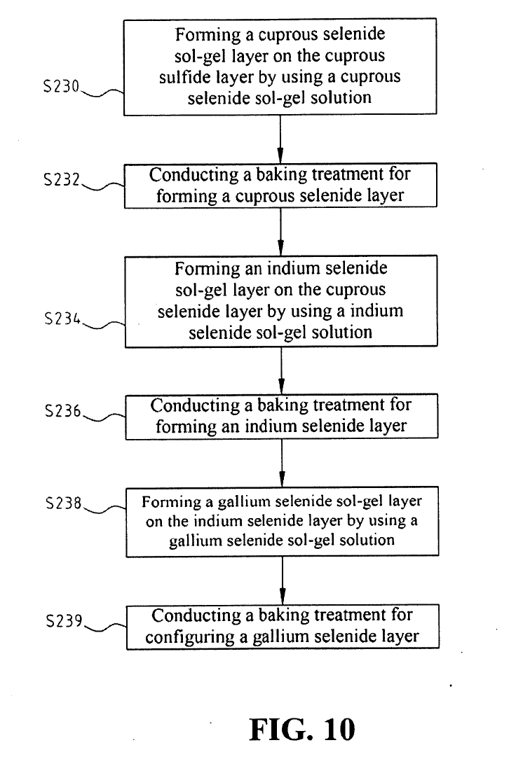

FIG. 10 illustrates the flow chart of forming the CIGS stack layers of the second embodiment of the present invention. Referring to FIG. 10, in step S230, using a cuprous selenide sol-gel solution, a cuprous selenide sol-gel layer is formed on the cuprous sulfide layer by conducting an immersion coating, spin coating, printing, or spray coating process, and then the flow enters step S232. In step S232, a baking treatment is conducted thereto at a baking temperature in a range from 60° C. to 150° C. for 10 to 20 minutes, during which the solvent contained in the cuprous selenide sol-gel layer is removed, and therefore a cuprous selenide layer is formed. The flow then enters step S234. In step S234, using an indium selenide sol-gel solution, an indium selenide sol-gel layer is formed on the cuprous selenide layer by conducting an immersion coating, spin coating, printing, or spray coating process, and then the flow enters step S236. In step S236, a baking treatment is conducted thereto at a baking temperature in a range from 60° C. to 150° C. for 10 to 20 minutes, during which the solvent contained in the indium selenide sol-gel layer is removed, and therefore an indium selenide layer is formed. The flow then enters step S238. In step S238, using a gallium selenide sol-gel solution, a gallium selenide sol-gel layer is formed on the indium selenide layer by conducting an immersion coating, spin coating, printing, or spray coating process, and then the flow enters step S239. In step S239, a baking treatment is conducted thereto at a baking temperature in a range from 60° C. to 150° C. for 10 to 20 minutes, during which the solvent contained in the gallium selenide sol-gel layer is removed, and therefore a gallium selenide layer is formed. In such a way, a CIGS stack layer including a cuprous selenide layer, an indium selenide layer, and a gallium selenide layer is formed.

The second embodiment of the present invention is preferably further conducted with a melting thermal treatment as depicted in the first embodiment of the present invention, for forming a CIGSS light absorbing layer having a high light absorbance.

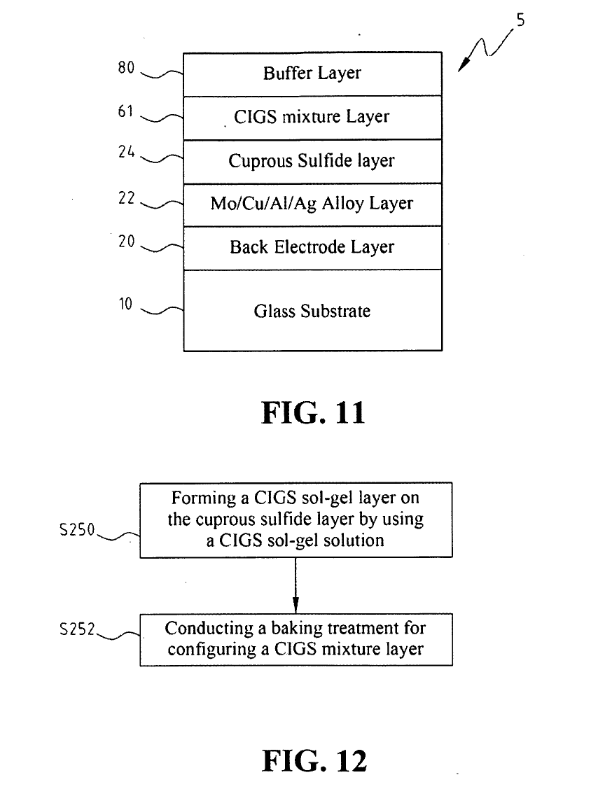

FIG. 11 is a schematic diagram illustrating a structure of a third embodiment of the present invention. Referring to FIG. 11, a CIGS solar cell 5 is shown. The CIGS solar cell 5 includes a glass substrate 10, a molybdenum (Mo) thin film layer serving as a back electrode layer 20, a Mo/Cu/Al/Ag alloy layer 22, a cuprous sulfide layer 24, a Cu/In/Ga/Se (CIGS) mixture layer 61, and a buffer layer 80 sequentially stacked one on another from bottom to top. Specifically, the cuprous sulfide layer 24, and the CIGS mixture layer 61 are sequentially stacked onto the Mo/Cu/Al/Ag alloy layer 22. The CIGS mixture layer 61 includes cuprous selenide, indium selenide, and gallium selenide. A thermal treatment is conducted to the cuprous sulfide layer 24, and the CIGS mixture layer 61, so that the cuprous sulfide layer 24 and the CIGS mixture layer 61 are molten and mutually diffused to form a copper/indium/gallium/sulfur/selenium (CIGSS) light absorbing layer having a high light absorbance. Then, the buffer layer 80 and a transparent electrode layer (not shown in the drawing) are sequentially deposited onto the CIGS mixture layer 61.

The cuprous sulfide layer 24 is similar as depicted in FIG. 4, and therefore the formation of the cuprous sulfide layer 24 is not iterated hereby.

FIG. 12 illustrates the flow chart of forming the CIGS stack layers of the third embodiment of the present invention. Referring to FIG. 12, in step S250, using a Cu/In/Ga/Se (CIGS) sol-gel solution containing a mixture of cuprous selenide, indium selenide, and gallium selenide, a CIGS sol-gel layer is formed on the cuprous sulfide layer by conducting an immersion coating, spin coating, printing, or spray coating process, and then the flow enters step S252. In step S252, a baking treatment is conducted thereto at a baking temperature in a range from 60° C. to 150° C. for 10 to 20 minutes, during which the solvent contained in the CIGS sol-gel layer is removed, and therefore a Cu/In/Ga/Se (CIGS) mixture layer including cuprous selenide, indium selenide, and gallium selenide is configured. In such a way, a CIGS stack layer including a cuprous selenide layer, an indium selenide layer, and a gallium selenide layer is formed.

The third embodiment of the present invention is preferably further conducted with a melting thermal treatment as depicted in the first embodiment of the present invention, for forming a CIGSS light absorbing layer having a high light absorbance.

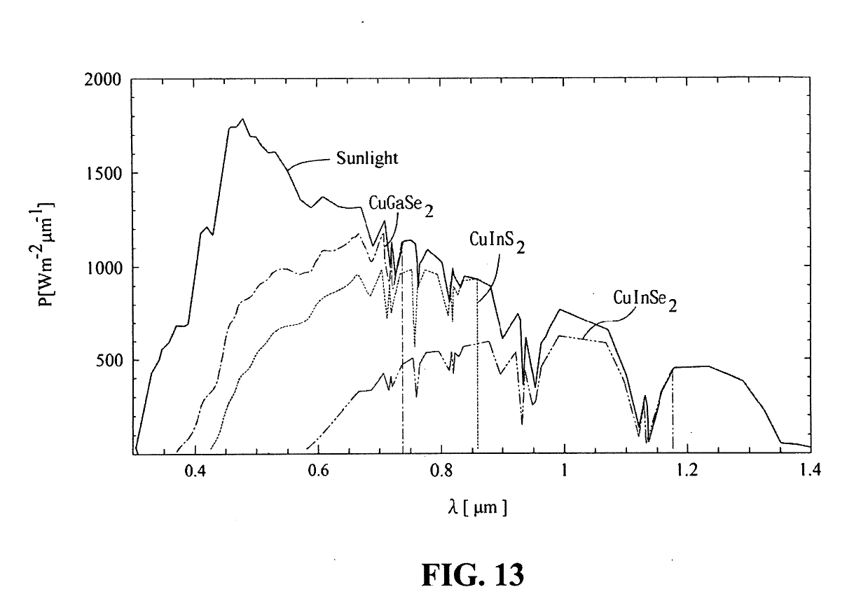

FIG. 13 shows a thin film absorption spectrum of the present invention. Referring to FIG. 13, it can be learnt that the CIGSS light absorbing layer contains CuInS₂, which can absorb light within the wavelength range from 700 nm to 900 nm. As such, the overall photoelectric transformation efficiency of the CIGS solar cell can be improved.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1 A light absorbing layer of a solar cell, the light absorbing layer being provided on a metal layer or a buffer layer, the light absorbing layer comprising a sulfur-contained buffer layer and a copper/indium/gallium/selenium (CIGS) mixture layer, the CIGS mixture layer comprising a plurality of composites constituted of copper, indium, gallium, and selenium, wherein the sulfur-contained buffer layer and the CIGS mixture layer are treated by a melting thermal treatment to form a copper/indium/gallium/sulfide/selenium (CIGSS) light absorbing layer.

2. The light absorbing layer according to claim 1, wherein the metal layer is a molybdenum (Mo) layer configured on a substrate.

3. The light absorbing layer according to claim 1, wherein the buffer layer comprises a Mo/Cu/Al/Ag alloy layer configured on a molybdenum (Mo) layer which is configured on a substrate.

4. The light absorbing layer according to claim 1, wherein the sulfur-contained buffer layer comprises cuprous sulfide.

5. The light absorbing layer according to claim 1, wherein the composites comprise cuprous selenide, indium selenide, and gallium selenide.

6. A light absorbing layer of a solar cell, the light absorbing layer being provided on a metal layer or a buffer layer, the light absorbing layer comprising a sulfur-contained buffer layer and a plurality of stack layers, the stack layers comprising a plurality of composites constituted of copper, indium, gallium, and selenium, wherein the sulfur-contained buffer layer and the stack layers are treated by a melting thermal treatment to form a copper/indium/gallium/sulfide/selenium (CIGSS) light absorbing layer.

7. The light absorbing layer according to claim 6, wherein the metal layer is a molybdenum (Mo) layer configured on a substrate.

8. The light absorbing layer according to claim 6, wherein the buffer layer comprises a Mo/Cu/Al/Ag alloy layer configured on a molybdenum (Mo) layer which is configured on a substrate.

9. The light absorbing layer according to claim 6, wherein the sulfur-contained buffer layer comprises cuprous sulfide.

10. The light absorbing layer according to claim 6, wherein the stack layers comprise a cuprous selenide layer, an indium selenide layer, and a gallium selenide layer.

11. The light absorbing layer according to claim 6, wherein the stack layers comprises a first mixture layer, a second mixture layer, and a third mixture layer, wherein the first mixture layer comprises cuprous selenide and gallium selenide, the second mixture layer comprises indium selenide and gallium selenide, and the third mixture layer comprises cuprous selenide and indium selenide.

12. A method for fabricating a light absorbing layer of a solar cell, the light absorbing layer being configured on a metal layer or a buffer layer, the metal layer being a molybdenum (Mo) layer provided on a substrate, the buffer layer being a Mo/Cu/Al/Ag alloy layer configured on the Mo layer, the method comprising:
conducting a sputtering process using a cuprous sulfide as a sputtering target to form a cuprous sulfide layer on the metal layer or the buffer layer;
providing a plurality of sol-gel solutions for configuring a CIGS stack layer on the cuprous sulfide layer by conducting a stack layer forming process, wherein the sol-gel solutions comprise a solvent and a plurality of composites constituted of copper, indium, gallium, and selenium; and
conducting a melting thermal treatment to the sulfur-contained buffer layer and the CIGS stack layer so that the sulfur-contained buffer layer and the CIGS stack layer are molten and mutually diffused, thus configuring a copper/indium/gallium/sulfide/selenium (CIGSS) light absorbing layer.

13. The method according to claim 12, wherein the sol-gel solutions comprise a CIGS sol-gel solution comprising cuprous selenide, indium selenide, gallium selenide, and the solvent, and the stack layer forming process comprises the steps of:
conducting an immersion coating, spin coating, printing, or spray coating process to coat the CIGS sol-gel solution onto the cuprous sulfide layer to form a CIGS sol-gel layer; and
baking the CIGS sol-gel layer for removing the solvent to form the CIGS stack layer comprising cuprous selenide, indium selenide, and gallium selenide.

14. The method according to claim 13, wherein the baking treatment is conducted by maintaining a temperature in a range from 60° C. to 150° C. for 10 to 20 minutes.

15. The method according to claim 12, wherein the sol-gel solutions comprises a cuprous selenide sol-gel solution, an indium selenide sol-gel solution, and a gallium selenide sol-gel solution, wherein the cuprous selenide sol-gel solution comprises cuprous selenide and the solvent, the indium selenide sol-gel solution comprises indium selenide and the solvent, and the gallium selenide sol-gel solution comprises gallium selenide and the solvent, wherein the stack layer forming process comprises the steps of:
conducting an immersion coating, spin coating, printing, or spray coating process to coat the cuprous selenide sol-gel solution onto the cuprous sulfide layer to form a cuprous selenide sol-gel layer;
baking the cuprous selenide sol-gel layer for removing the solvent to form a cuprous selenide layer;
conducting an immersion coating, spin coating, printing, or spray coating process to coat the indium selenide sol-gel solution onto the cuprous selenide layer to form an indium selenide sol-gel layer;
baking the indium selenide sol-gel layer for removing the solvent to form an indium selenide layer;
conducting an immersion coating, spin coating, printing, or spray coating process to coat the gallium selenide sol-gel solution onto the indium selenide layer to form a gallium selenide sol-gel layer;
baking the gallium selenide sol-gel layer for removing the solvent to form a gallium selenide layer; and
forming the CIGS stack layer comprising the cuprous selenide layer, the indium selenide layer, and the gallium selenide layer.

16. The method according to claim 15, wherein the baking treatment is conducted by maintaining a temperature in a range from 60° C. to 150° C. for 10 to 20 minutes.

17. The method according to claim 12, wherein the sol-gel solutions comprise:
a first sol-gel solution comprising cuprous selenide, gallium selenide, and the solvent;
a second sol-gel solution comprising indium selenide, gallium selenide and the solvent; and
a third sol-gel solution comprising cuprous selenide, indium selenide, and the solvent, and
wherein the stack layer forming process comprises the steps of:
conducting an immersion coating, spin coating, printing, or spray coating process to coat the first sol-gel solution onto the cuprous sulfide layer to form a first sol-gel layer;
baking the first sol-gel layer for removing the solvent to form a first mixture layer;
conducting an immersion coating, spin coating, printing, or spray coating process to coat the second sol-gel solution onto the first mixture layer to form a second sol-gel layer;
baking the second sol-gel layer for removing the solvent to form a second mixture layer;
conducting an immersion coating, spin coating, printing, or spray coating process to coat the third sol-gel solution onto the second mixture layer to form a third sol-gel layer;
baking the third sol-gel layer for removing the solvent to form a third mixture layer; and
forming the CIGS stack layer comprising the first mixture layer, the second mixture layer, and the third mixture layer.

18. The method according to claim 17, wherein the baking treatment is conducted by maintaining a temperature in a range from 60° C. to 150° C. for 10 to 20 minutes.

19. The method according to claim 12, wherein the melting thermal treatment comprises:
conducting a rapid thermal process with a temperature rising rate of 5° C./sec to 10° C./sec to raise the temperature up to a melting temperature in a range from 400° C. to 800° C.;
conducting a constant temperature melting treatment at the melting temperature for about 10 minutes to 20 minutes; and
conducting a fast cooling treatment by introducing a cooling gas to lower the temperature down to 50° C. to 200° C. taking about 40 minutes to 180 minutes.

20. The method according to claim 19, wherein the cooling gas comprises argon gas or nitrogen gas.
